(19) United States
(12) Patent Application Publication
(10) Pub. No.: US 2012/0064455 A1
(43) Pub. Date: Mar. 15, 2012

(54) PHOTORESIST COMPOSITION AND METHOD OF FORMING PATTERN USING THE SAME

(75) Inventors: Dong-Guk YU, Changwon-si (KR); Ki-Soo KIM, Changwon-si (KR); Hyun-Tae LIM, Changwon-si (KR)

(73) Assignee: SAMSUNG TECHWIN CO., LTD., Changwon-si (KR)

(21) Appl. No.: 13/179,106

(22) Filed: Jul. 8, 2011

(30) Foreign Application Priority Data
Sep. 13, 2010 (KR) 10-2010-0089422

(51) Int. Cl. G03F 7/20; G03F 7/004

(52) U.S. Cl. 430/270.1; 430/323

(57) ABSTRACT

A photoresist composition and method of forming a pattern using the same are provided. The photoresist composition includes a 60 to 90 wt % novolac resin, a diazide compound, an organic solvent, and an anticorrosive agent.

### CROSS-REFERENCE TO RELATED APPLICATION

This application claims priority from Korean Patent Application No. 10-2010-0089422 filed on Sep. 13, 2010 in the Korean Intellectual Property Office, the disclosure of which in its entirety is incorporated herein incorporated by reference.

### BACKGROUND

1. Field

Apparatuses and methods consistent with exemplary embodiments relate to a photoresist composition and a method of forming a pattern using the same, and more particularly to, a photoresist composition used to form a pattern on a substrate and a method of forming a pattern using the same.

2. Description of the Related Art

A photoresist is used in photolithography for forming various patterns. The photoresist refers to a photosensitive resin which changes solubility in a developing solution by action of light to thereby obtain an image corresponding to an exposure pattern. A photoresist is referred to as a positive photoresist if a portion of the photoresist exposed to light has an increased solubility in a developing solution and the exposed portion is removed in a development process to form a desired pattern. In contrast, a photoresist is referred to as a negative photoresist if a portion of the photoresist exposed to light has a largely reduced solubility in a developing solution and a non-exposed portion is removed in a development process to form a desired pattern.

After a photoresist mixed with a solvent and the like is coated on a substrate, exposure and development are performed to form a structure having a predetermined pattern. A technique for forming a pattern using the photoresist is widely applied to various fields.

Generally, in a method of forming a circuit on a substrate, a mask is formed using the photoresist and an etching solution is coated to form a circuit in a desired pattern. Various etching solutions are used according to a pitch of a desired pattern. Particularly, in case of a fine pattern pitch equal to or smaller than 30 μm, there is a limit to forming a circuit by using a general etching solution.

As shown in FIGS. 1A-1D, the general etching solution permeates into a metal layer 20 to cause isotropic etching. Accordingly, it is difficult to anisotropically etch the metal layer 20 only in a vertical direction with respect to the base member 10 to form a fine pattern in the metal layer 20. That is, when a pattern mask 30 is formed using a photoresist and an etching solution is provided to the substrate including the metal layer 20, the etching solution permeates into the photoresist pattern mask 30, and is uniformly diffused in all directions to etch the metal layer 20. Consequently, as shown in FIGS. 1A-1D, the metal layer 20 is etched in a hemispherical shape. Accordingly, adjacent grooves formed in the metal layer 20 may communicate with each other or a wall between the grooves may become thin. Thus, there is a limit to miniaturization of a pitch of a pattern to be formed in the metal layer 20.

### SUMMARY

One or more exemplary embodiments provide a photoresist composition capable of achieving anisotropic etching using a general etching solution without an anticorrosive agent and an organic matter, thereby forming a fine pattern with a narrow pitch.

One or more exemplary embodiments also provide a method of forming a pattern, wherein a fine pattern is formed by using a general etching solution without an organic matter, and it is possible to improve a production yield and reduce a defect ratio because there is no organic matter remaining on the substrate, thereby providing advantages in cost reduction.

According to an aspect of an exemplary embodiment, there is provided a photoresist composition including a 60 to 90 wt % novolac resin, a diazide compound, an organic solvent, and an anticorrosive agent.

According to an aspect of another exemplary embodiment, there is provided a method of forming a pattern using a photoresist, including forming a photoresist layer containing an anticorrosive agent and having an opening in a predetermined pattern on a substrate, providing an etching solution to the substrate, and forming an anticorrosive film on a side surface of a groove which is etched downward through the opening by the etching solution.

According to an aspect of still another exemplary embodiment, there is provided a method of forming a pattern using a photoresist, including forming an anticorrosive film by coating an anticorrosive agent on a substrate, forming a photoresist layer having an opening in a predetermined pattern on the anticorrosive film on the substrate, providing an etching solution to the substrate, and forming an anticorrosive film on a side surface of a groove which is etched downward through the opening by the etching solution.

Aspects of other exemplary embodiments are included in the detailed description and drawings.

### BRIEF DESCRIPTION OF THE DRAWINGS

The above and other aspects will become more apparent by describing in detail exemplary embodiments with reference to the attached drawings, in which:

FIGS. 1A to 1D illustrate an etching shape formed by a method of forming a pattern using a related art photoresist;

FIGS. 2A to 2D illustrate an etching shape formed by a method of forming a pattern using a photoresist in accordance with an exemplary embodiment;

FIG. 3 is a flowchart showing a method of forming a pattern using a photoresist, in accordance with an exemplary embodiment;

FIGS. 4A to 4F illustrate sequential steps of a pattern forming method using a photoresist in accordance with an exemplary embodiment;

FIG. 5 is a flowchart showing a method of forming a pattern using a photoresist in accordance with another exemplary embodiment; and

FIGS. 6A to 6G illustrate sequential steps of a pattern forming method using a photoresist in accordance with another exemplary embodiment.

### DETAILED DESCRIPTION OF EXEMPLARY EMBODIMENTS

Exemplary embodiments will be described in detail below with reference to the accompanying drawings. The inventive concept may, however, be embodied in many different forms and should not be construed as being limited to the exemplary embodiments set forth herein. Rather, these exemplary embodiments are provided so that this disclosure will be thorough and complete and will fully convey the inventive concept to those skilled in the art, and the inventive concept will only be defined by the appended claims. In the drawings, the size and relative sizes of layers and regions may be exaggerated for clarity.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present. Throughout the specification, like reference numerals in the drawings denote like elements. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures.

The exemplary embodiments are described herein with reference to plan and cross-section illustrations that are schematic illustrations of idealized exemplary embodiments. As such, variations from the shapes of the illustrations as a result, for example, of manufacturing techniques and/or tolerances, are to be expected. Thus, the exemplary embodiments should not be construed as limited to the particular shapes of regions illustrated herein but are to include deviations in shapes that result, for example, from manufacturing.

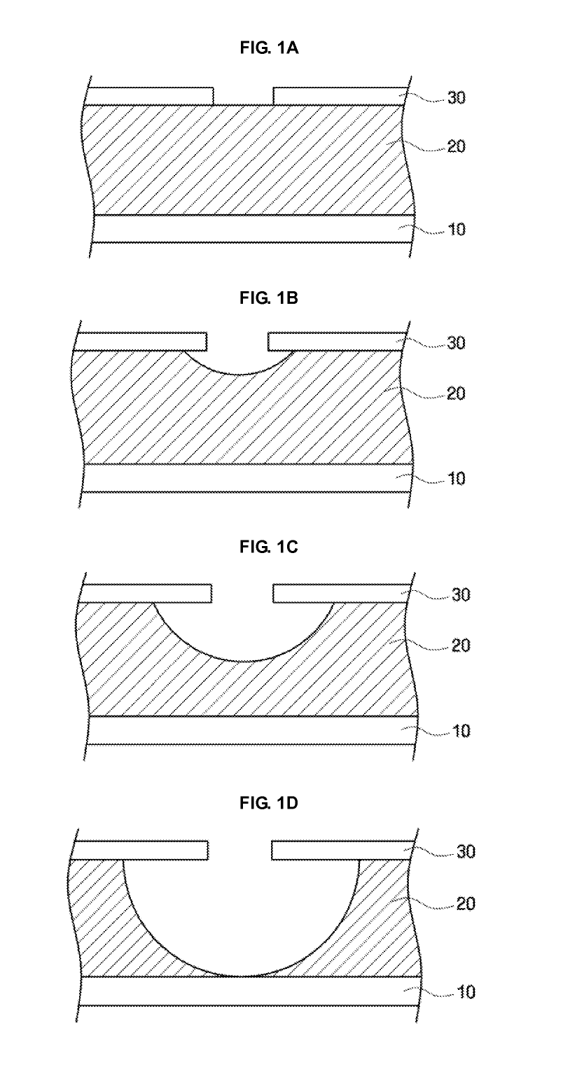

According to an exemplary embodiment, a fine circuit pattern is able to be formed on a substrate by using an etching solution having components different from those of a general etching solution or mixing an etching solution with an additive, in comparison with the method of forming a pattern using a related art photoresist as shown in FIGS. 1A to 1D. Particularly, an anticorrosive agent may be added to the etching solution to prevent isotropic etching as shown in FIGS. 1A to 1D. Accordingly, the substrate can be etched to have a fine pitch in a thickness direction of the substrate, i.e., in a direction perpendicular to the substrate.

However, since the anticorrosive agent included in the etching solution has no affinity for water, an organic matter such as a dispersion stabilizer and an emulsifier may also be added to protect the anticorrosive component. The added organic matter may be completely removed even after a subsequent cleaning process, thereby reducing a production yield or causing a defect.

Meanwhile, a semi-additive method for forming a fine pattern without adding an anticorrosive agent and an organic matter is a method of forming a circuit having a pitch of 15 μm or less by using a dry film photoresist (DFR) to manufacture a product by plating. However, a process is complicated and the number of steps increases. Thus, it is not desirable in the cost and productivity aspects.

Hereinafter, a photoresist composition and a method of forming a pattern using the same in accordance with an exemplary embodiments will be described with reference to the accompanying drawings.

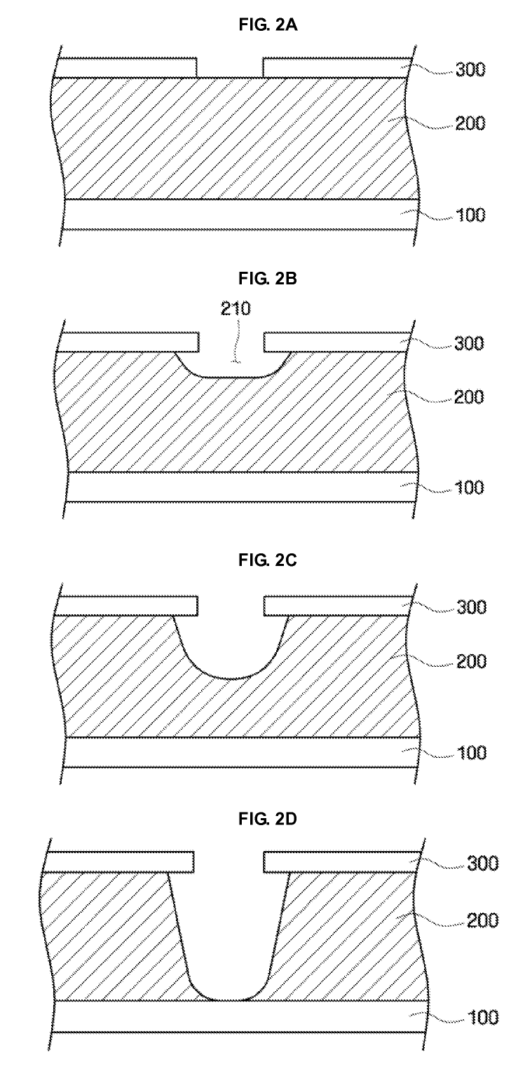

A photoresist composition and a method of forming a pattern using the same in accordance with an exemplary embodiment will be described with reference to FIGS. 2A to 2D, 3 and 4A to 4F.

First, FIGS. 2A-2D illustrate sequentially etched shapes in a method of forming a pattern using a photoresist composition in accordance with an exemplary embodiment. That is, an etching mask, which is a photoresist layer 300, is formed on a pattern layer 200 formed on a base member 100 by using a photoresist composition, and anisotropic etching is performed by a general etching solution without an additive. Consequently, an etched groove 210 is formed in the pattern layer 200 in a vertical column shape, instead of a hemispherical shape, with respect to the based member 100.

Accordingly, since the etching solution does not include an additive such as organic matter, a foreign matter remaining after a cleaning process is reduced, thereby improving a production yield of a finished substrate having a pattern and reducing a defect ratio. Thus, there is an effect of reducing the production cost.

The photoresist composition in accordance with the exemplary embodiment having the above effect includes a 60 to 90 wt % novolac resin, a diazide compound, an organic solvent and an anticorrosive agent.

The novolac resin may include a phenolic compound, and may include at least one of a phenolic compound, an aldehyde compound, a ketone compound. Alternatively, the novolac resin may be obtained by reacting two or more compounds of the phenolic compound, the aldehyde compound, and the ketone compound in the presence of an acid catalyst.

The novolac resin may contain meta-cresol and para-cresol. The novolac resin may contain meta-cresol present in an amount of 60 wt % or more with respect to the total weight of the novolac resin and a residual amount of para-cresol, preferably but not necessarily, meta-cresol present in an amount of 60 to 90 wt % and a residual amount of para-cresol. If the content of the meta-cresol of the novolac resin is smaller than about 60 wt %, although light is irradiated uniformly onto a photoresist layer 300, there occurs a large difference in the photoresist reaction. Accordingly, a pattern of the photoresist layer 300 has a non-uniform thickness. Particularly, uniformity of a remaining film thickness is deteriorated at a half-exposed portion. If the pattern of the photoresist layer 300 has a non-uniform thickness, it reduces reliability of a fine pattern formed in the pattern layer 200 disposed below the photoresist layer 300 by using the photoresist layer 300 as an etch stop layer. On the other hand, if the content of the meta-cresol of the novolac resin is larger than about 90 wt %, because the content of the para-cresol of the novolac resin becomes relatively small, it may be difficult to control sensitivity of the photoresist composition including the novolac resin.

The phenolic compound to be included in the novolac resin may include at least one selected from the group consisting of ortho-cresol, meta-cresol, para-cresol, 2,3-dimethylphenol, 3,4-dimethylphenol, 3,5-dimethylphenol, 2,4-dimethylphenol, 2,6-dimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol. 2-isopropylphenol, 2-methoxy-5-methylphenol, 2-t-butyl-5-methylphenol, thymol, and isothymol.

The aldehyde compound to be included in the novolac resin may include at least one selected from the group consisting of formaldehyde, paraformaldehyde, propionaldehyde, butylaldehyde, valeraldehyde, glyoxal, glutaraldehyde, and dialdehyde starch.

The ketone compound to be included in the novolac resin may include at least one selected from the group consisting of acetone, methyl ethyl ketone, diethyl ketone, methyl isobutyl ketone, cyclohexanone, and cyclopentanone.

The diazide compound may include at least one of a photosensitizer and a phenolic compound. If the diazide compound includes both the photosensitizer and the phenolic compound, the phenolic compound may serve as a ballast. Preferably, but not necessarily, the average molecular weight of the diazide compound including the phenolic compound serving as a ballast is about 1,000 to 4,000.

The photosensitizer adjusts a photosensitivity when light is irradiated onto the photoresist layer 300. The photosensitizer to be included in the diazide compound may include at least one selected from the group consisting of 1,2-naphthoquinonediazide-5-sulfonate, 2,3,4-trihydroxybenzophenone-1,2-naphthoquinonediazide-5-sulfonate and 2,3,4,4′-tetrahydroxybenzophenone-1,2-naphthoquinonediazide-5-sulfonate. That is, these materials can be used singly or in combination as the photosensitizer. In the present exemplary embodiment, 2,3,4-trihydroxybenzophenone-1,2-naphthoquinonediazide-5-sulfonate may be preferably used as the photosensitizer, but it is not limited thereto.

The phenolic compound serves to increase an adhesive property by increasing an attractive force between the pattern layer 200 of the base member 100 and the novolac resin. That is, the phenolic compound may improve adhesive strength between the pattern layer 200 and the photoresist layer 300 by uniformly distributing the novolac resin in the organic solvent in the photoresist composition in accordance with an exemplary embodiment. In addition, the phenolic compound serves as a ballast to stably combine the photosensitizer with the phenolic compound.

The phenolic compound to be included in the diazide compound may include at least one selected from the group consisting of ortho-cresol, meta-cresol, para-cresol, 2,3-dimethylphenol, 3,4-dimethylphenol, 3,5-dimethylphenol, 2,4-dimethylphenol, 2,6-dimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol. 2-isopropylphenol, 2-methoxy-5-methylphenol, 2-t-butyl-5-methylphenol, thymol, and isothymol.

No particular limitation is imposed on the organic solvent to be used in the present exemplary embodiment. Specifically, the organic solvent may include at least one of alcohol, ether, glycol ether, acetate, diethylene glycol, propylene glycol monoalkyl ether, propylene glycol alkyl ether acetate, propylene glycol alkyl ether propionate, aromatic hydrocarbon, ketone and ester.

More specifically, the organic solvent of the present exemplary embodiment may include at least one selected from the group consisting of alcohol such as methanol and ethanol; ether such as tetrahydrofuran; glycol ether such as ethylene glycol monomethyl ether and ethylene glycol monoethyl ether; ethylene glycol alkyl ether acetate such as methyl cellosolve acetate and ethyl cellosolve acetate; diethylene glycol such as diethylene glycol monomethyl ether, diethylene glycol monoethyl ether and diethylene glycol dimethyl ether; propylene glycol monoalkyl ether such as propylene glycol methyl ether, propylene glycol ethyl ether, propylene glycol propyl ether, propylene glycol butyl ether; propylene glycol alkyl ether acetate such as propylene glycol methyl ether acetate, propylene glycol ethyl ether acetate, propylene glycol propyl ether acetate and propylene glycol butyl ether acetate; propylene glycol alkyl ether propionate such as propylene glycol methyl ether propionate, propylene glycol ethyl ether propionate, propylene glycol propyl ether propionate and propylene glycol butyl ether propionate; aromatic hydrocarbon such as toluene and xylene; ketone such as methylethylketone, cyclohexanone and 4-hydroxy-4-methyl-2-pentanon; and ester such as methyl acetate, ethyl acetate, propyl acetate, butyl acetate, 2-hydroxyethyl propionate, 2-hydroxy-2-methylmethyl propionate, 2-hydroxy-2-methylethyl propionate, hydroxymethyl acetate, hydroxyethyl acetate, hydroxybutyl acetate, methyl lactate, ethyl lactate, propyl lactate, butyl lactate, 3-hydroxymethyl propionate, 3-hydroxyethyl propionate, 3-hydroxypropyl propionate, 3-hydroxybutyl propionate, 2-hydroxy-3-methylbutyric acid methyl, methoxy methyl acetate, methoxy ethyl acetate, methoxy propyl acetate, methoxy butyl acetate, ethoxy methyl acetate, ethoxy ethyl acetate, ethoxy propyl acetate, ethoxy butyl acetate, propoxy methyl acetate, propoxy ethyl acetate, propoxy propyl acetate, propoxy butyl acetate, butoxy methyl acetate, butoxy ethyl acetate, butoxy propyl acetate, butoxy butyl acetate, 2-methoxymethyl propionate, 2-methoxyethyl propionate, 2-methoxypropyl propionate, 2-methoxybutyl propionate, 2-ethoxymethyl propionate, 2-ethoxyethyl propionate, 2-ethoxypropyl propionate, 2-ethoxybutyl propionate, 2-butoxymethyl propionate, 2-butoxyethyl propionate, 2-butoxypropyl propionate, 2-butoxybutyl propionate, 3-methoxymethyl propionate, 3-methoxyethyl propionate, 3-methoxypropyl propionate, 3-methoxybutyl propionate, 3-ethoxymethyl propionate, 3-ethoxyethyl propionate, 3-ethoxypropyl propionate, 3-ethoxybutyl propionate, 3-propoxymethyl propionate, 3-propoxyethyl propionate, 3-propoxypropyl propionate, 3-propoxybutyl propionate, 3-butoxymethyl propionate, 3-butoxyethyl propionate, 3-butoxypropyl propionate and 3-butoxybutyl propionate.

The anticorrosive agent is a material preventing metal from being etched. The anticorrosive agent prevents lateral etching in the etched groove 210, thereby allowing the etched groove 210 to be formed in the pattern layer 200 in a vertical shape with respect to the base member 100. Accordingly, it is possible to provide a substrate having a fine pattern in which the etched groove 210 is separated from an adjacent groove by a narrow distance in the base member 100.

The anticorrosive agent may include at least one of a heterocyclic compound having a carbonyl group, a glycol compound having a triple bond, an metal salt compound of alkyl sarcosine, an anhydrous compound of aromatic carboxylic acid, and thiazole and triazole compounds. Preferably, but not necessarily, the anticorrosive agent may include thiazole and triazole compounds and a heterocyclic compound having a carbonyl group.

The heterocyclic compound having a carbonyl group may include at least one of coumarin, uracil, nicotinic acid, isocinchomeronic acid and citric acid.

The glycol compound having a triple bond may include at least one of 2-butyl-1,4-diol and 2,4,7,9-tetramethyl-5-decyne-4,7-diol.

The metal salt compound of alkyl sarcosine may include at least one of N-lauroylsarcosine, Na or K salt of N-lauroylsarcosine, N-oleoylsarcosine, and Na or K salt of N-oleoylsarcosine.

The anhydrous compound of aromatic carboxylic acid may include at least one of phthalic anhydride, trimellitic anhydride, and pyromellitic anhydride.

The thiazole and triazole compounds may include at least one of benzotriazole and 2-aminobenzothiazole.

Meanwhile, the photoresist composition of the present exemplary embodiment may further include an additive such as a coloring agent, a dye, a plasticizer and a surfactant, if necessary, in order to improve performance in each step of photolithography.

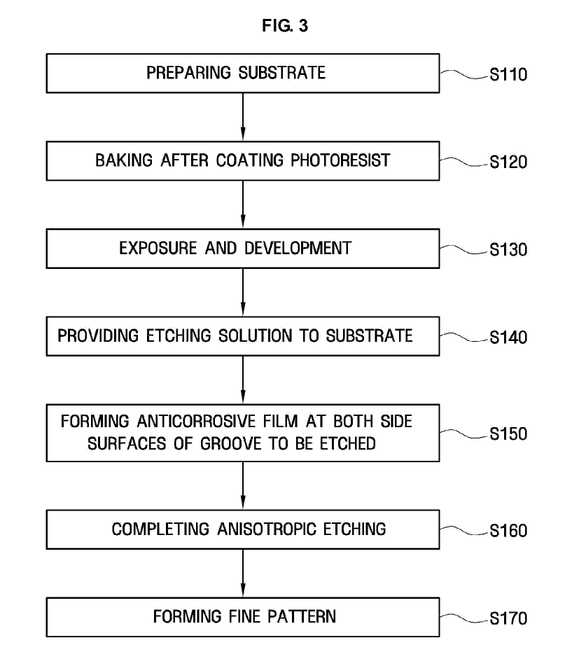

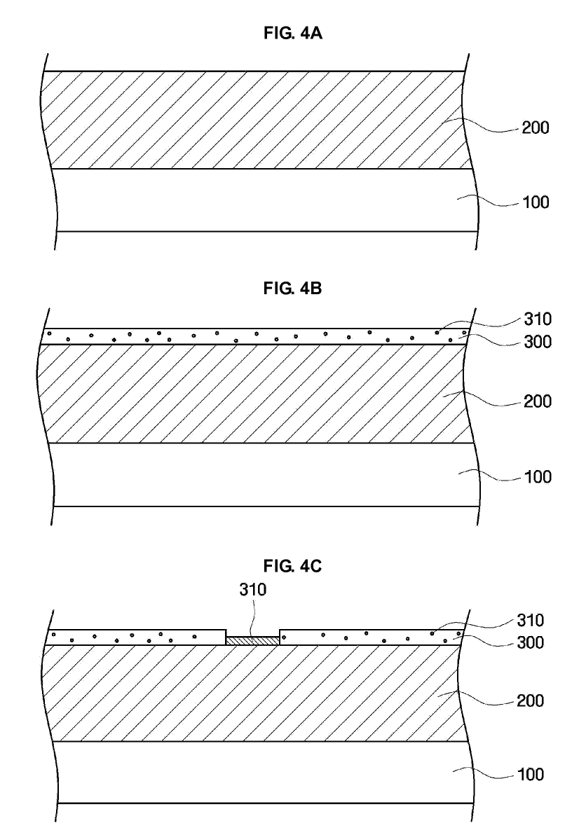

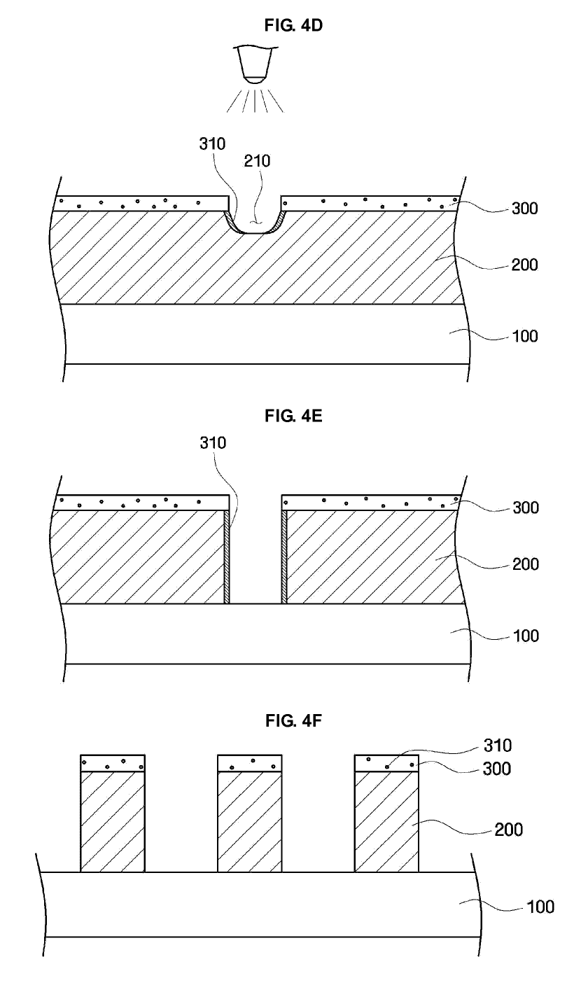

Hereinafter, a method of forming a pattern using a photoresist composition in accordance with an exemplary embodiment will be described with reference to FIGS. 3 and 4.

The method of forming a pattern using the photoresist composition in accordance with the exemplary embodiment includes a step of forming a photoresist layer containing an anticorrosive agent and having an opening in a predetermined pattern on a substrate, a step of providing an etching solution to the substrate, and a step of forming an anticorrosive film on a side surface of a groove to be etched downward through the opening by the etching solution.

First, a substrate is prepared (S110). As shown in FIG. 4A, the substrate includes the base member 100 and the pattern layer 200. According to an exemplary embodiment, the pattern layer 200 may be a metal layer and referred to as a metal layer 200 hereinafter.

No particular limitation is imposed on the type of the base member 100, and the base member 100 may be formed of various materials according to the purpose of the substrate. In case of a chip on film (COF) substrate used in a liquid crystal display device, the base member 100 may be formed of a transparent material capable of transmitting light, i.e., glass, a transparent plastic film or sheet. For example, the transparent plastic film may include a polycarbonate material, a polysulfone material, a polyacrylate material, a polystyrene material, a polyvinyl chloride material, a polyvinyl alcohol material, a polynorbornene material, or a polyester material. For example, the base member 100 may include polyethylene terephthalate, polyethylene naphthalate or the like. Alternatively, the base member 100 may be formed of a polycarbonate material, a polyethersulfone material, or a polyarylate material, which is a transparent, flexible material, so as to be applicable to a flexible display device.

The metal layer 200 is a layer on which a circuit pattern is formed. The metal layer 200 may be formed of metal having conductivity, e.g., copper or silver.

Subsequently, as shown in FIG. 4B, a photoresist composition is coated on the metal layer 200 of the substrate and a baking process is performed to form the photoresist layer 300 (S120).

The photoresist composition coated on the metal layer 200 may include an anticorrosive agent 310. The anticorrosive agent 310 may include at least one of a heterocyclic compound having a carbonyl group, a glycol compound having a triple bond, an metal salt compound of alkyl sarcosine, an anhydrous compound of aromatic carboxylic acid, and thiazole and triazole compounds.

In addition, the photoresist composition may further include a novolac resin, a diazide compound and an organic solvent. Since these materials have been described above, a repeated description thereof is omitted.

The photoresist composition may be coated on the metal layer 200 by spin coating. The spin coating may be performed at various rotation speeds to control a thickness of the photoresist layer 300. The photoresist composition may be coated on the substrate by using another coating method such as roller coating, bar coating, slot coating, dip coating, gravure coating and spray coating in addition to spin coating.

Dry baking is performed to evaporate the solvent from the coated photoresist composition, thereby forming the photoresist layer 300 as a photosensitive film without viscosity. Generally, the photoresist composition is dried by using a hot plate under the condition that a drying time period at a temperature of 65° C. is one minute to five minutes and a drying time period at a temperature of 95° C. is five minutes to thirty minutes or longer if necessary. In this case, the substrate is made to be in contact with or adjacent to the surface of the hot plate. Such dry baking may be performed in a convection oven.

Subsequently, exposure and development are performed on the photoresist layer 300 to fabricate a pattern mask having an opening as shown in FIG. 4C (S130).

Specifically, a pattern mask having a reverse pattern of a desired pattern is deposited on the photoresist layer 300 formed on the base member 100. Then, exposure may be performed through a pattern mask having opaque and transparent regions by using radiation of X rays from a standard or synchrotron light source or radiation of near ultraviolet rays having a wavelength ranging from 300 nm to 50 nm from a medium-pressure or high-pressure mercury lamp. Alternatively, photographic image processing may be performed by an electron beam through a direct or patterned exposure. A contact printing method, a proximity printing method, or a projection printing method may be used. For example, ultraviolet (UV) rays, X rays and electron beam radiation may be used in the exposure. Specifically, radiation of ultraviolet (UV) rays and X rays may be active radiation, and UV rays emitted from a mercury lamp at a wavelength of 365 nm, 405 nm and 436 nm may be used. It is possible to provide light having a single wavelength through a photomask by using an appropriate optical filter. The above exposure process is exemplary and a wavelength of light used in the exposure and specific conditions may be modified.

After exposure, post-exposure baking may be performed to accelerate acid catalyst polymerization at a region of the photoresist layer 300 which has been exposed to light. Generally, the post-exposure baking may be carried out by using a hot plate under the condition that a drying time period at a temperature of 65° C. is one minute and a drying time period at a temperature of 95° C. is five minutes. The temperature and time conditions may vary according to products. Then, in order to dissolve a non-polymerized region, the photoresist layer 300 is impregnated with an organic solvent developer according to a desired thickness of the photoresist layer 300 and the solvent strength of the developer, typically, for two minutes to five minutes. The remaining developer is removed by washing the developed image with a cleaning solvent.

Through this process, as shown in FIG. 4C, the photoresist layer 300 having an opening may be used as an etching mask. In this case, the anticorrosive agent 310 in the photoresist composition remains at a position where the opening is formed through the exposure and development to form a thin film.

Subsequently, the metal layer 200 is etched by providing an etching solution onto the substrate (S130). In this case, as shown in FIG. 4D, the photoresist layer 300 having an opening is used as an etching mask, and the etching solution is selectively provided to only a portion of the metal layer 200 which is exposed to the outside through the opening to cause a reaction. As described above, the etching solution may not include an organic matter and an anticorrosive agent having no affinity for water.

Subsequently, while the metal layer 200 is etched by the etching solution, the anticorrosive agent 310 forming a thin film at the opening forms an anticorrosive film at both side surfaces of the etched groove 210, thereby preventing lateral etching (S150). As explained above with reference to FIG. 1, if isotropic etching is carried out by a general etching solution, the metal layer 200 is etched in a hemispherical shape by the etching solution provided to the metal layer 200. Accordingly, as shown in FIG. 1, a hemispherical etching groove may be formed to cause difficulty in forming a fine pattern.

In order to prevent this phenomenon, the anticorrosive agent 310 included in the photoresist composition forms a thin film at side surfaces (sidewalls) of the etched groove 210 etched by the etching solution, thereby causing anisotropic etching. This is because the anticorrosive agent 310 is hardly mixed with water and moves to the side surfaces of the etched groove 210 away from the etching solution. Accordingly, it is possible to increase a production yield and reduce a defect ratio by including only an anticorrosive agent in the photoresist composition to form a vertically uniform etched groove 210 instead of adding an anticorrosive agent and an organic matter to the etching solution.

By continuing this process, as shown in FIG. 4E, the etched groove 210 having a uniform width in a direction perpendicular to the base member 100 is formed to complete anisotropic etching (S160).

Subsequently, as shown in FIG. 4F, the metal layer 200 is etched in a desired shape to form a predetermined pattern. Particularly, it is possible to precisely form a fine pattern having a pitch of 15 μm or less by the method of forming a pattern in accordance with an exemplary embodiment (S170).

Thereafter, the remaining photoresist composition and anticorrosive agent are removed by a cleaning process for injecting a cleaning solution such as deionized water. Then, the substrate is dried by a drying process for offering a drying solution such as isopropyl alcohol (IPA), thereby finishing the process.

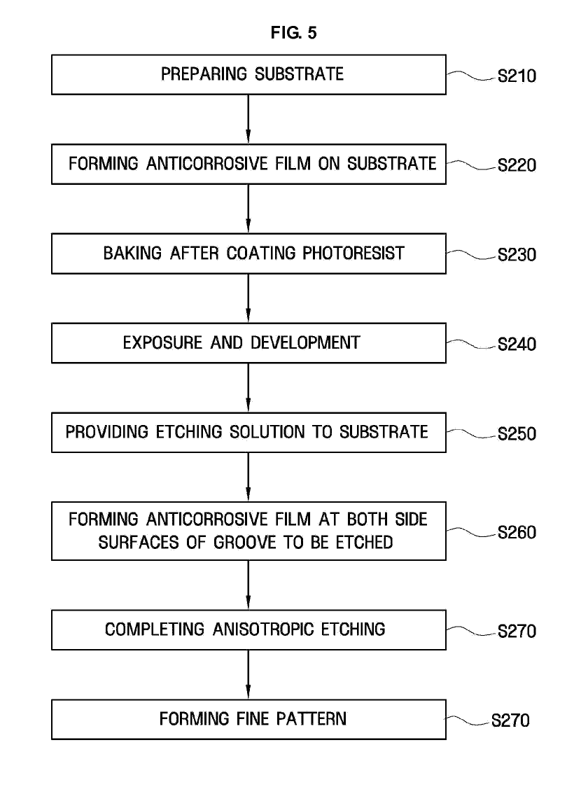

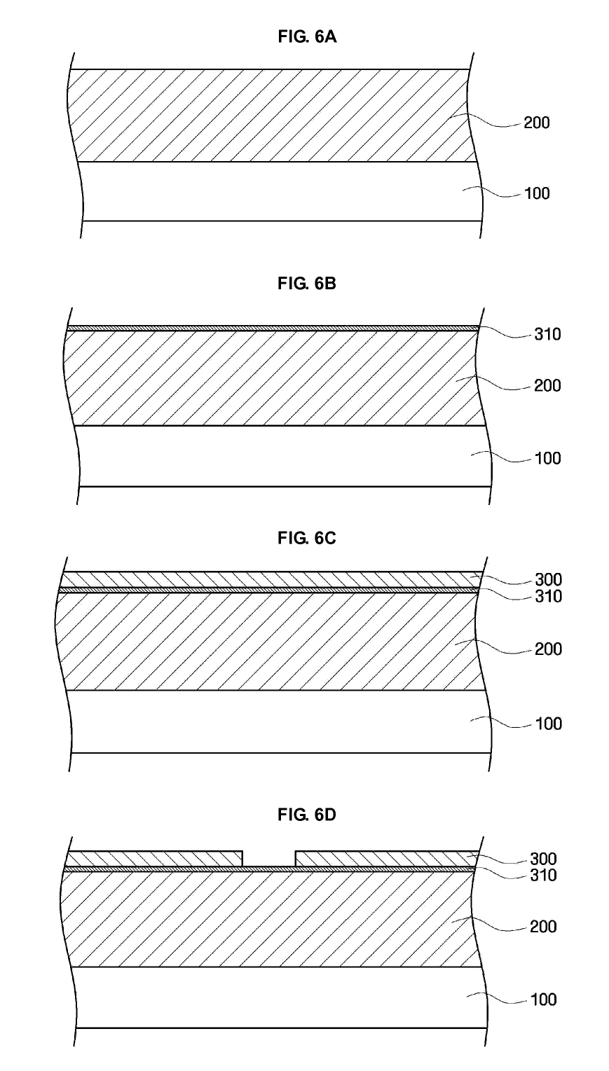

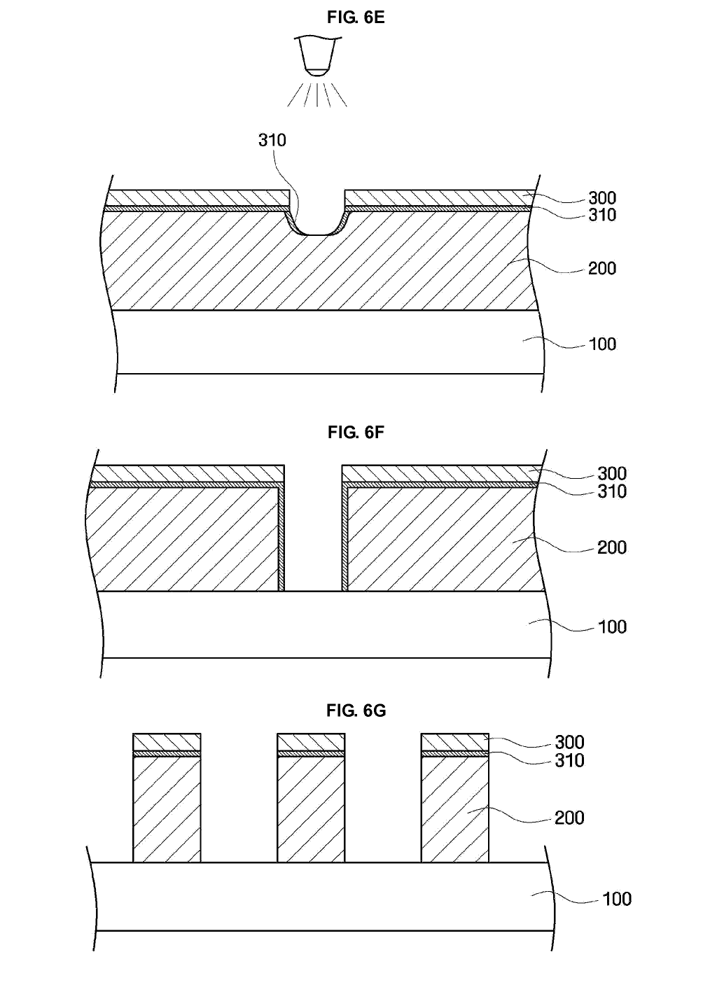

Hereinafter, a method of forming a pattern using a photoresist composition in accordance with another exemplary embodiment will be described with reference to FIGS. 5 and 6.

The method of forming a pattern using a photoresist composition in accordance with another exemplary embodiment includes forming an anticorrosive film by coating an anticorrosive agent on a substrate, forming a photoresist layer having an opening in a predetermined pattern on the anticorrosive film on the substrate, providing an etching solution on the substrate, and forming an anticorrosive film at side surfaces of a groove etched downward through the opening by the etching solution.

That is, as shown in FIGS. 5 and 6B to 6D, unlike the previous exemplary embodiment, first, an anticorrosive film 310 is formed on the metal layer 200 and a photoresist layer 300 is formed thereon. In this case, because the anticorrosive film 310 is separately provided, the photoresist composition to form the photoresist layer 300 may not include an anticorrosive agent.

Other steps are performed in a similar manner as in the previous exemplary embodiment. That is, a substrate is prepared as shown in FIG. 6A (S210), and the anticorrosive film 310 is formed as shown in FIG. 6B (S220). Then, the photoresist layer 300 is formed thereon as shown in FIG. 6C (S230), and exposure and development are carried out to form the photoresist layer 300 to be used as an etching pattern mask as shown in FIG. 6D (S240). Then, the metal layer 200 is etched by providing an etching solution as shown in FIG. 6E (S250), and while the metal layer 200 is etched by the etching solution, the anticorrosive agent forming the thin anticorrosive film 310 at the opening moves to the side surfaces (sidewalls) of the etched groove 210 to form a thin film at side surfaces, thereby preventing lateral etching, as shown in FIG. 6F (S260). Then, anisotropic etching is completed (S270), thereby finishing a substrate having a predetermined pattern in which the metal layer 200 is etched in a desired shape, as shown in FIG. 6G (S280).

In a similar manner as in the previous exemplary embodiment, it is possible to form a fine pattern in a vertical direction because the anticorrosive film 310 prevents lateral etching of the etching solution.

While the exemplary embodiments have been particularly shown and described, it will be understood by those of ordinary skill in the art that various changes in form and detail may be made therein without departing from the spirit and scope of the inventive concept as defined by the following claims. The exemplary embodiments should be considered in a descriptive sense only and not for purposes of limitation.

What is claimed is:

1. A photoresist composition comprising:
a 60 to 90 wt % novolac resin;
a diazide compound;
an organic solvent; and
an anticorrosive agent.

2. The photoresist composition of claim 1, wherein the novolac resin comprises a phenolic compound.

3. The photoresist composition of claim 2, wherein the novolac resin comprises meta-cresol present in an amount of at least 60 wt % and a residual amount of para-cresol.

4. The photoresist composition of claim 1, wherein the diazide compound includes at least one of a photosensitizer and a phenolic compound.

5. The photoresist composition of claim 4, wherein an average molecular weight of the diazide compound ranges from 1,000 to 4,000.

6. The photoresist composition of claim 1, wherein the organic solvent comprises at least one of alcohol, ether, glycol ether, acetate, diethylene glycol, propylene glycol monoalkyl ether, propylene glycol alkyl ether acetate, propylene glycol alkyl ether propionate, aromatic hydrocarbon, ketone and ester.

7. The photoresist composition of claim 1, wherein the anticorrosive agent comprises at least one of a heterocyclic compound having a carbonyl group, a glycol compound having a triple bond, an metal salt compound of alkyl sarcosine, an anhydrous compound of aromatic carboxylic acid, and thiazole and triazole compounds.

8. The photoresist composition of claim 7, wherein the thiazole and triazole compounds include at least one of benzotriazole and 2-aminobenzothiazole.

9. A method of forming a pattern using a photoresist, the method comprising:
forming a photoresist layer containing an anticorrosive agent and having an opening in a predetermined pattern on a substrate;
providing an etching solution to the substrate; and
forming an anticorrosive film on a side surface of a groove which is etched downward through the opening by the etching solution.

10. The method of claim 9, wherein the etching solution does not include an organic matter and an anticorrosive agent.

11. The photoresist composition of claim 9, wherein the anticorrosive agent comprises at least one of a heterocyclic compound having a carbonyl group, a glycol compound having a triple bond, an metal salt compound of alkyl sarcosine, an anhydrous compound of aromatic carboxylic acid, and thiazole and triazole compounds.

12. The photoresist composition of claim 11, wherein the anticorrosive agent comprises thiazole and triazole compounds and a heterocyclic compound having a carbonyl group.

13. The photoresist composition of claim 11, wherein the thiazole and triazole compounds comprise at least one of benzotriazole and 2-aminobenzothiazole.

14. A method of forming a pattern using a photoresist, comprising:
forming an anticorrosive film by coating an anticorrosive agent on a substrate;
forming a photoresist layer having an opening in a predetermined pattern on the anticorrosive film on the substrate;
providing an etching solution to the substrate; and
forming an anticorrosive film on a side surface of a groove which is etched downward through the opening by the etching solution.

15. The method of claim 14, wherein the etching solution does not include an organic matter and an anticorrosive agent.

16. The photoresist composition of claim 14, wherein the anticorrosive agent comprises at least one of a heterocyclic compound having a carbonyl group, a glycol compound having a triple bond, an metal salt compound of alkyl sarcosine, an anhydrous compound of aromatic carboxylic acid, and thiazole and triazole compounds.

17. The photoresist composition of claim 16, wherein the anticorrosive agent comprises thiazole and triazole compounds and a heterocyclic compound having a carbonyl group.

18. The photoresist composition of claim 16, wherein the thiazole and triazole compounds comprise at least one of benzotriazole and 2-aminobenzothiazole.
